(19) United States
(12) Patent Application Publication
(10) Pub. No.: US 2011/0272005 A1
(43) Pub. Date: Nov. 10, 2011

(54) BACKSHEET FOR PHOTOVOLTAIC MODULE

(75) Inventor: Stephen Yau-Sang CHENG, Hong Kong (HK)

(73) Assignee: Du Pont Apollo Limited, Hong Kong (HK)

(21) Appl. No.: 13/102,065

(22) Filed: May 6, 2011

Related U.S. Application Data
(60) Provisional application No. 61/332,872, filed on May 10, 2010.

(51) Int. Cl. H01L 31/048; B32B 9/04; B32B 27/00; B32B 37/14

(52) U.S. Cl. 136/251; 156/279; 428/411.1; 428/500

(57) ABSTRACT

A rapid-crystallizing polymer, which can rapidly crystallize from its melted state to solid state, is used to be the insulation layer of the polymer backsheet for photovoltaic modules.

### RELATED APPLICATIONS

This application claims priority to U.S. Provisional Application Ser. No. 61/332,872, filed May 10, 2010, which is herein incorporated by reference.

### BACKGROUND

1. Technical Field

The disclosure relates to a photovoltaic module. More particularly, the disclosure relates to a backsheet for a photovoltaic module.

2. Description of Related Art

Photovoltaic (PV) modules are large-area optoelectronic devices that convert solar radiation directly into electrical energy. Most PV modules presently use discrete crystalline-silicon solar cells that are connected in an electrical circuit and encapsulated with a glass cover and polymer backsheet for environmental protection.

Polymer backsheet is a laminated structure. Polyethylene terephthalate (PET) is the most commonly used material for the insulation layer of the polymer backsheet to provide electrical insulation and mechanical structure for the polymer backsheet. Moreover, the crystallinity of PET is important to maintain the dimensional stability of the PET sheet at various processing temperatures for fabricating the PV modules. For example, the encapsulation process is performed at a typical temperature of 120-150° C., if not higher. However, the crystallization rate of PET is quite slow. Hence, PET needs to be pre-processed to increase the crystallinity to provide enough dimensional stability for the polymer backsheet. Consequently, PET sheets can only come as a pre-fabricated material, and then incorporated via a separate lamination step onto the laminates of the polymer backsheet. That is, PET must undergo sheet fabrication, orientation and lamination steps in order to be used as the insulation layer in the polymer backsheet. Additional processes for lamination, includes surface treatment of the PET film, is not considered'yet.

### SUMMARY

Accordingly, a rapid-crystallizing polymer, which can rapidly crystallize from its melted state to solid state, is used to be the insulation layer of the polymer backsheet to simplify the fabrication process of the polymer backsheet is in one aspect.

According to an embodiment of this invention, the rapid-crystallizing polymer can crystallize at least 20% of its maximum crystallinity at solid state from its melted state to solid state, and the crystallinity of the rapid-crystallizing polymer at solid state is at least 10% to maintain the dimensional stability of the insulation layer.

According to another embodiment of this invention, the crystallites of the rapid-crystallizing polymer is melted at or above 100° C. to maintain the dimensional stability of the insulation layer in the subsequent processes, such as encapsulating process, for fabricating photovoltaic modules.

According to another embodiment of this invention, the melted rapid-crystallizing polymer can be directly applied onto a barrier layer of the polymer backsheet. The melted rapid-crystallizing polymer can be cooled down naturally, or cooled down by air convection or water quenching in a continuous or discontinuous profile. Therefore, no glue material between the rapid-crystallizing polymer and the barrier layer is needed for attaching the rapid-crystallizing polymer to the barrier layer.

According to another embodiment of this invention, the rapid-crystallizing polymer can be polybutylene terephthalate (PBT), for example. Some to nucleating agents, additives, fillers, and/or other suitable polymers can be added in to the rapid-crystallizing polymer.

It is to be understood that both the foregoing general description and the following detailed description are by examples, and are intended to provide further explanation of the invention as claimed.

### BRIEF DESCRIPTION OF THE DRAWINGS

FIG. 1 is a cross-sectional diagram of a portion of obtained backsheet structure according to one embodiment of this invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

Existing polymer backsheets (abbreviated as backsheets below) are laminated structures. The fabrication process of the existing backsheets involves lamination of a weather resistant layer, a barrier layer, and a pre-fabricated PET sheet by using glue material therebetween. The weather resistant layer is usually a fluorinated polymer, such as polyvinyl fluoride (PVF), and the barrier layer is usually an aluminum foil. The PET sheet is used as an insulation layer of the backsheet.

As stated above, a rapid-crystallizing polymer, which can rapidly crystallize from its melted state to solid state, is used as the insulation layer in the backsheet to simplify the fabrication process of the backsheet. Therefore, the polymer layer, i.e. the insulation layer of the backsheet, does not need to be pre-fabricated, and the melted rapid-crystallizing polymer can be directly applied onto the barrier layer to form the solid polymer layer. It does not need any glue material between the polymer layer and the barrier layer.

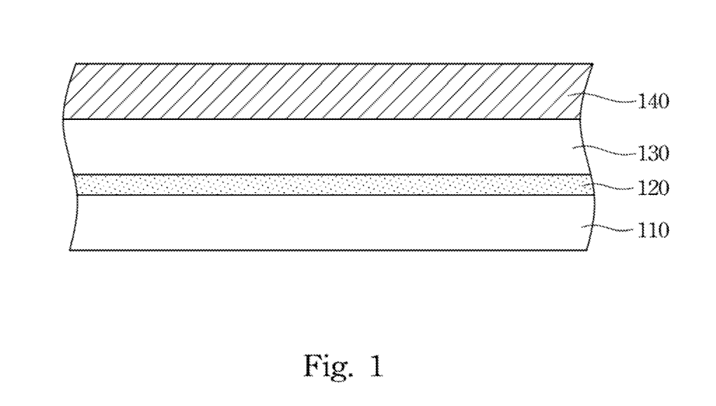

Accordingly, FIG. 1 is a cross-sectional diagram of a portion of obtained backsheet structure according to one embodiment of this invention. In the FIG. 1, melted rapid-crystallizing polymer can be directly applied to a barrier layer 130 by a thermoplastic process, such as extrusion coating, and can be cooled down to form a solid polymer layer 140 on the barrier layer 130. A weather resistant layer 110 can be adhered to the barrier layer 130 through a glue layer 120.

In order to maintain the dimensional stability of the polymer layer 140, the crystallinity of the final polymer layer 140 is at least 10%, preferably at least 20%, and more preferably at least 40%. The definition of crystallinity is defined by IUPAC (International Union of Pure and Applied Chemistry) Definition of Terms Relating to Crystalline Polymers (1988), which is entirely incorporated here by reference.

In order to maintain the dimensional stability of the polymer sheet 140 at various processing temperatures, the crystallite of the polymer sheet 140 can be only melted at or above 100° C., preferably at or above 140° C., or more preferably at or above 180° C.

The melted rapid-crystallizing polymer can be cooled down naturally, or to can be cooled down by air convection or water quenching in a continuous or discontinuous profile, for example. If the melted rapid-crystallizing polymer is naturally cooled down, the cooling rate can be as high as 200° C./min. If the melted rapid-crystallizing polymer is cooled down by water quenching, the cooling rate can be as high as 2000° C./min. There is no special limitation about the cooling step. The only requirement needs to be met in the cooling step is that the rapid-crystallizing polymer can crystallize at least 20%, preferably at least 40%, and more preferably at least 60% of its maximum crystallinity at solid state in a limited time period from melted state to solid state of the rapid-crystallizing polymer.

The rapid-crystallizing polymer can be polybutylene terephthalate (PBT), for example. PBT can maintain its dimensional stability above the Tg of about 40° C. Moreover, in the cooling of the melted PBT, the rapidly formed crystallite is not melted until a temperature above 200° C. Therefore, rapid-crystallizing PBT can maintain its dimensional stability at or above 200° C. to meet the requirements of fabricating the backsheet.

The crystallizing rate of the rapid-crystallizing polymer can be affected by various factors. One factor is an inherent property of the rapid-crystallizing polymer. Another factor can be blend effect due to blending another polymer into the rapid-crystallizing polymer. In addition, nucleating agents are usually used to increase the crystallizing rate of polymer. For example, dibenzylidene sorbitol is usually used to increase the crystallization rate of polyester, such as PET or PBT.

For imparting various properties and processing characteristics to the rapid-crystallizing polymer, some other polymer can be incorporated into the is rapid-crystallizing polymer. When the rapid-crystallizing polymer is PBT, polycarbonate, other polyesters, ethylenevinylacetate (EVA) and functionalized EVA, for example, can be blended with PBT.

Some additives, such as but not limited to UV stabilizers, antioxidants, or a combination thereof, can be added into the rapid-crystallizing polymer. UV stabilizers can be hindered amine light stabilizers, for example. Antioxidants can be phosphites, for example. In addition, fillers, such as but not limited to calcium carbonate, talc, or a combination thereof, can also be added into the rapid-crystallizing polymer. Processing aids, such as anti-blocking agents, can also be added into the rapid-crystallizing polymer. The anti-blocking agents can be CESA-block 1501 from Clariant used in the manufacturing of PET or PBT films, for example.

The thickness of the polymer layer 140 can be 0.01-2.0 mm, preferably 0.1-0.5 mm. If the thickness of the polymer layer 140 is too thin, the rigidity of the polymer layer 140 may not be enough to provide sufficient mechanical support for the backsheet. The upper limit of the thickness of the polymer layer 140 is limited by practical considerations, such as additional cost and space constraints. As long as the thickness exceeds that required to provide electrical insulation, environmental and physical protection, increasing thickness is not necessary. However, if the polymer layer 140 is too thin, there are some other ways to provide sufficient mechanical support for the backsheet. For example, the thickness of encapsulant of the backsheet can be increased to compensate the thickness of the polymer layer 140.

The barrier layer 130 in FIG. 1 can be a metal foil, a polymer film, a metalized polymer film, or an inorganic oxide coated polymer film, for example. The barrier layer 130 can be further surface-treated to increase the adhesive strength with the polymer layer 140. When the barrier layer 130 is a metal foil, such as aluminum foil, the surface treatment can be surface roughening, oxidative treatment, or chemical priming. When the barrier layer 130 is a polymer film, such as polyvinylidene chloride (PVDC), polyvinyl fluoride (PVF), ethylene chlorotrifluoroethlyene (ECTFE), or other fluoropolymer, the surface treatment can be corona treatment, surface roughening, oxidative treatment, or chemical priming. When the barrier layer 130 is a metalized polymer film, such as aluminum coated polymer film, the surface treatment can be conversion coating process to enhance the adhesion characteristics of the aluminum layer. When the barrier layer 130 is an inorganic oxide, such as silicon oxide, coated polymer film, the surface treatment can be chemical priming.

For example, when an aluminum foil is used as the barrier layer, the surface can be treated by a conversion coating containing chromate or phosphates and then be primed with a polymers such as ethylene acrylic acid copolymers or ethylene maleic anhydride copolymers to improve adhesion to other polymer materials.

The weather resistant layer 110 in FIG. 1 can be a fluorinated polymer, such as polyvinyl fluoride. The weather resistant layer 110 is used to protect the photovoltaic module in the outdoor environment.

Some embodiments of this invention are described below. In the first embodiment, an un-reinforced PBT resin (Dupont Crastin® 6129C NC010) can be used to form the polymer layer 140 in FIG. 1, and aluminum foil can be used as the barrier layer 130 in FIG. 1. The heat deflection temperature of the un-enforced PBT is about 115° C. under a pressure of 0.45 MPa. The un-enforced PBT resin can be melted and then extrusion coated onto the aluminum foil, which has been pre-coated with a terpolymer of ethylene, butylacrylate and maleic anhydride (Archema Lotader 3210) grafted layer to promote adhesion strength between the PBT and the aluminum.

In the second embodiment, a glass-fiber enforced PBT resin (Crastin®LW9020 BK580) can be used form the polymer layer 140 in FIG. 1, and aluminum foil can be used as the barrier layer 130 in FIG. 1. The heat deflection temperature of the glass-fiber enforced PBT is about 205° C. under a pressure of 0.45 MPa. The glass-fiber enforced PBT resin can be melted and then extrusion coated onto the aluminum foil, which has been pre-coated with a terpolymer of ethylene, butylacrylate and maleic anhydride (Archema Lotader 3210) grafted layer to promote adhesion strength between the PBT and the aluminum.

Accordingly, a rapid-crystallizing polymer is used as the insulation layer in the backsheet to simplify the fabrication process of the backsheet, since the melted rapid-crystallizing polymer can be directly applied onto the barrier layer to form the solid polymer layer. Thus, it does not need any glue material between the polymer layer and the barrier layer.

The reader's attention is directed to all papers and documents which are filed concurrently with this specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, each feature disclosed is one example only of a generic series of equivalent or similar features.

What is claimed is:

1. A photovoltaic module, wherein the backsheet of the photovoltaic module comprising:
a weather resistant layer;
a glue layer on the weather resistant layer;
a barrier layer on the adhesive layer; and
a polybutylene terephthalate (PBT) layer on the barrier layer, wherein there is no glue material between the PBT layer and the barrier layer.

2. The photovoltaic module of claim 1, wherein the PBT layer is reinforced by glass fibers.

3. The photovoltaic module of claim 1, wherein the crystallinity of the PBT layer is at least 10% to maintain the dimensional stability of the PBT layer.

4. The photovoltaic module of claim 1, wherein the crystallites of the PBT layer is melted at or above 100° C. to maintain the dimensional stability during encapsulation process for encapsulating photovoltaic cells of the photovoltaic module.

5. The photovoltaic module of claim 1, wherein the thickness of the PBT layer is at least 0.1 mm to ensure enough rigidity of the PBT layer.

6. The photovoltaic module of claim 1, wherein the barrier layer is a metal foil, a polymer film, a metalized polymer film, or an inorganic oxide coated polymer film.

7. The photovoltaic module of claim 1, wherein the weather resistant layer is made from a fluorinated polymer.

8. A method of fabricating a backsheet of a photovoltaic module, the method comprising:
coating melted polybutylene terephthalate (PBT) on a first surface of a barrier layer;
cooling the melted PBT to obtain a solid PBT layer on the barrier layer; and
adhering a weather resistant layer on a second surface of the barrier layer, wherein the second surface is opposite to the first surface of the barrier layer.

9. The method of claim 8, wherein the melted PBT is reinforced by glass fibers.

10. The method of claim 8, wherein the melted PBT is cooled down naturally, or cooled down by air convection or water quenching in a continuous or discontinuous profile.

11. The method of claim 8, wherein the cooling rate of the melted PBT is smaller than 2000° C./min.

12. The method of claim 8, wherein the melted PBT can crystallize at least 20% of solid PBT's maximum crystallinity in the cooling step.

13. The method of claim 12, wherein the maximum crystallinity of the solid PBT layer is at least 10%.

14. The method of claim 8, wherein the thickness of the solid PBT layer is at least 0.1 mm to ensure enough rigidity of the PBT layer.

15. The method of claim 8, wherein the barrier layer is a metal foil, a polymer film, a metalized polymer film, or an inorganic oxide coated polymer film.

16. The method of claim 15, wherein the barrier layer can have the first surface treated to improve adhesion between the barrier layer and the PBT layer.

17. The method of claim 16, wherein the weather resistant layer is made from a fluorinated polymer.

18. A backsheet of a photovoltaic module, the backsheet comprising:
a weather resistant layer;
an adhesive layer on the weather resistant layer;
a barrier layer on the adhesive layer; and
an insulation layer, made from a rapid-crystallizing polymer, directly on a barrier layer, wherein the rapid-crystallizing polymer can crystallize at least 20% of its maximum crystallinity from its melted state to solid state, and wherein the crystallinity of the rapid-crystallizing polymer is at least 10%.

19. The backsheet of claim 18, wherein the crystallite of the rapid-crystallizing polymer is melted at or above 100° C.

20. The backsheet of claim 18, wherein the rapid-crystallizing polymer is polybutylene terephthalate.
